(19) United States
(12) Patent Application Publication
(10) Pub. No.: US 2026/0280449 A1
(43) Pub. Date: Sep. 17, 2026

(54) BONDING PILLAR STRUCTURE FOR HIDDEN COMB MICROELECTROMECHANICAL SYSTEM

(71) Applicant: Lumentum Operations LLC, San Jose, CA (US)

(72) Inventors: Wenlin JIN, Ottawa (CA); Parsoua ABEDINI SOHI, Nepean (CA); John Michael MILLER, Gatineau (CA); Edward WANG, Ottawa (CA); Jino FATHY, Ottawa (CA)

(21) Appl. No.: 19/255,275

(22) Filed: Jun. 30, 2025

Related U.S. Application Data
(60) Provisional application No. 63/769,995, filed on Mar. 11, 2025.

(51) Int. Cl. H02N 1/00; B81B 7/00; B81C 1/00; G02B 26/08

(52) U.S. Cl. CPC H02N 1/006; B81B 7/0016; B81C 1/00825; G02B 26/0833; B81B 2201/033; B81B 2201/042; B81B 2203/0136; B81B 2203/0307; B81C 2201/013; B81C 2203/051

(57) ABSTRACT

In some implementations, a microelectromechanical system (MEMS) device includes a stator layer, comprising: an anchor structure, a stator structure attached to the anchor structure, and a set of bonding pillars configured to be attached to the anchor structure; a rotor layer disposed on the stator layer, comprising: a rotor structure, a hinge, and a set of rotor pillar regions, wherein each bonding pillar, of the set of bonding pillars, is configured to be bonded to a respective rotor pillar region of the set of rotor pillar regions; and a cover layer disposed on the rotor layer, comprising: a cover structure, and a set of cover pillar regions, wherein each cover pillar region, of the set of cover pillar regions, is bonded to a respective rotor pillar region of the set of rotor pillar regions.

### CROSS-REFERENCE TO RELATED APPLICATION

This Patent Application claims priority to U.S. Provisional Patent Application No. 63/769,995, filed on Mar. 11, 2025, and entitled “MICROELECTROMECHANICAL SYSTEM (MEMS) COMB STRUCTURE.” The disclosure of the prior Application is considered part of and is incorporated by reference into this Patent Application.

### TECHNICAL FIELD

The present disclosure relates generally to microelectromechanical systems and to a bonding pillar structure for a hidden comb microelectromechanical system device.

### BACKGROUND

A micro-electromechanical system (MEMS) device is a micro-sized mechanical structure that may include a mirror or other optical element for reflecting light. When the MEMS device is actuated, a mirror may be tilted about an axis, which may cause an optical beam that was falling upon the mirror and reflecting in one direction to fall upon the mirror and reflect in a different direction. The MEMS device may actuate (e.g., tilt) the mirror using an electrical impulse, such as by using a rotor-comb actuator.

### SUMMARY

In some implementations, a microelectromechanical system (MEMS) device includes a stator layer, comprising: an anchor structure, a stator structure attached to the anchor structure, and a set of bonding pillars configured to be attached to the anchor structure; a rotor layer disposed on the stator layer, comprising: a rotor structure, a hinge, and a set of rotor pillar regions, wherein each bonding pillar, of the set of bonding pillars, is configured to be bonded to a respective rotor pillar region of the set of rotor pillar regions; and a cover layer disposed on the rotor layer, comprising: a cover structure, and a set of cover pillar regions, wherein each cover pillar region, of the set of cover pillar regions, is bonded to a respective rotor pillar region of the set of rotor pillar regions.

In some implementations, a method of manufacturing a MEMS device includes forming, by a device, a stator wafer including a set of stator structures, wherein the set of stator structures includes a set of pillars; forming, by the device, a rotor wafer including a set of rotor structures, wherein the set of rotor structures include a set of bonding pillar areas; bonding, by the device, the set of pillars of the stator wafer to the set of bonding pillar areas of the rotor wafer; and detaching, by the device, the set of bonding pillar areas from the rotor wafer.

In some implementations, an optical system includes a MEMS device, comprising: a stator layer, comprising: an anchor structure, a stator structure attached to the anchor structure, and a set of bonding pillars configured to be attached to the anchor structure; a rotor layer disposed on the stator layer, comprising: a rotor structure, a hinge, and a set of rotor pillar regions, wherein each bonding pillar, of the set of bonding pillars, is configured to be bonded to a respective rotor pillar region of the set of rotor pillar regions; and a MEMS element disposed above the rotor layer, such that the MEMS element is movable in connection with movement of the rotor layer relative to the stator layer.

### BRIEF DESCRIPTION OF THE DRAWINGS

FIG. 1 is a diagram of an example implementation associated with bonding pillar structure for hidden comb microelectromechanical system.

FIGS. 2A-2C are diagrams of an example implementation associated with bonding pillar structure for hidden comb microelectromechanical system.

FIGS. 3A-3D are diagrams of an example implementation associated with bonding pillar structure for hidden comb microelectromechanical system.

FIG. 4 is a flowchart of an example process associated with using a bonding pillar structure for a hidden comb MEMS device.

### DETAILED DESCRIPTION

The following detailed description of example implementations refers to the accompanying drawings. The same reference numbers in different drawings may identify the same or similar elements.

An optical system may direct an optical beam (e.g., a laser beam) toward a target. For example, the optical system may include an optical communications system that directs an optical beam toward an optical device for communications, an optical measurement system that directs an optical beam toward a target to measure a reflection of the optical beam, an optical manufacturing system that directs an optical beam toward a target to effectuate a manufacturing process (e.g., laser cutting or laser welding), or an optical imaging system that obtains images at different angles or positions, among other examples. In one example, a vehicle, such as a semiautonomous or fully autonomous vehicle, may use a light detection and ranging (LIDAR) system to detect objects (e.g., other vehicles, pedestrians, or road debris) in a path of the vehicle. A typical LIDAR system includes a beam deflection unit that deflects both projected optical beams and reflected optical beams. Similarly, an optical communications system may include a beam deflection unit to direct an optical beam toward a desired optical path (e.g., as part of an optical circuit switch) or an optical manufacturing system may include a beam deflection unit to direct an optical beam toward a particular area of a target.

In some cases, an optical system may use one or more micro-electromechanical system (MEMS) devices to deflect optical beams. A MEMS device may use a multi-layer comb-actuator structure (e.g., a stator comb and a rotor comb) to provide a driving torque to tilt a mirror on a hinge of the MEMS device about an axis. Additionally, or alternatively, a MEMS device may use a set of parallel plates as actuating elements to drive an optical element, such as a mirror. The MEMS device may include a cover that encloses elements of the MEMS device, such as the rotor, the stator, or an optical element, to prevent particle contamination, which can cause failures or degradation in MEMS device performance.

In a hidden comb type of MEMS device, a rotor layer is suspended over a stator layer by a pair of hinges and is moved when a driving voltage is applied to the stator layer. Because of a difficulty in attaching a cover on top of a suspended rotor layer, the cover may be attached to the rotor layer before suspension above the stator layer and the cover and rotor layer may be attached to the stator layer in a reverse bonding sequence. In such a configuration, the rotor layer is supported by a handle during a first bonding to a cover and is supported by a set of anchor areas during a second bonding to the stator layer, with the rotor becoming suspended, between the set of anchor areas, above the stator layer.

However, reverse bonding using anchor areas can result in a large misalignment between the stator combs and the rotor combs. Accordingly, to avoid contact between the stator combs and the rotor combs, which would prevent the driving voltage from driving motion in the rotor layer, a relatively large gap must be configured between individual teeth of the stator combs and the rotor combs. The relatively large gap reduces driving force per tooth and limits a quantity of tooths per unit area, thereby limiting achievable driving force of the MEMS device. Additionally, when using a reverse bonding process, a tilting pivot location is fixed at one half of a thickness of a rotor layer. However, due to an added mass of a cover layer, a mass center location of the MEMS device is offset from the pivot. Accordingly, mechanical vibration or shocking in a lateral direction can generate tilting force with respect to the pivot, which can result in undesired mirror tilt. The undesired mirror tit results in poor performance of an optical system that includes the MEMS device.

Some implementations described herein provide a MEMS device with a set of bonding islands for attaching a rotor layer (and a cover) to a stator layer of a MEMS device. For example, a stator layer may include a set of bonding pillars that are bonded to a set of rotor pillar regions of a rotor layer. In this case, the rotor layer can be directly suspended above the stator layer without reverse bonding. The cover layer may include a set of cover bonding regions that are bonded to the set of rotor pillar regions. An etch procedure may be used to etch around the rotor pillar regions (and the cover bonding regions), thereby detaching a rotor comb of the rotor layer from the bonding pillars and the stator layer to which the bonding pillars attach. As a result, stator structures and rotor structures (of the stator layer and the rotor layer, respectively) can be aligned to the same alignment mark during formation, thereby achieving a higher inter-digitated alignment accuracy of stator teeth of the stator structures with rotor teeth of the rotor structures. By achieving a higher alignment accuracy (e.g., alignment to within a threshold tolerance level, such as to within 1 micrometer (μm)) a force per tooth can be increased and a density of teeth per unit area can be increased, thereby increasing an achievable driving force of the MEMS device. Additionally, or alternatively, by etching the rotor layer before bonding, a vertical location of a tilting pivot can be adjusted to match a mass center of the MEMS device (with the cover layer), thereby aligning the mass center with the tilting pivot. By aligning the mass center with the tilting pivot, the MEMS device may reduce a sensitivity to lateral shocking or vibration on an alignment of an optical element in the MEMS device (e.g., a mirror).

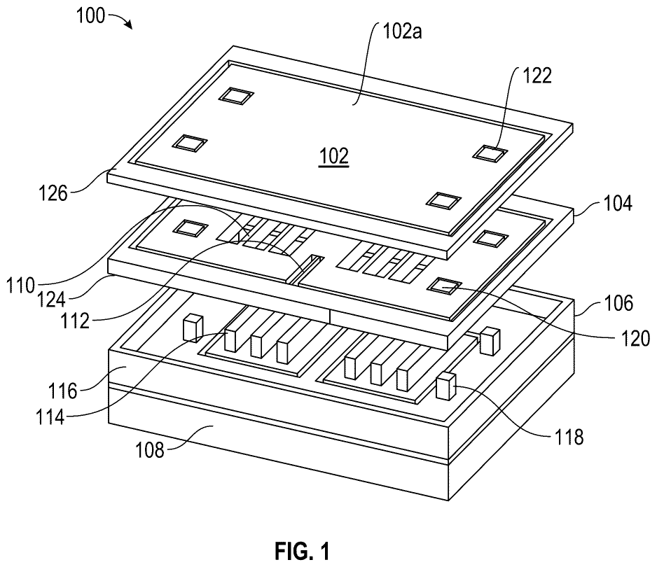

FIG. 1 is a diagram of an example MEMS device 100 associated with bonding pillar structure for a hidden comb microelectromechanical system. As shown in FIG. 1, a MEMS device 100 may include a three-layer MEMS mirror device that includes a cover layer 102, a rotor layer 104, and a stator layer 106. In some implementations, the stator layer 106 may be disposed on one or more substrate layers 108. For example, the stator layer 106 may be disposed on a handle layer, with an insulating layer disposed between the handle layer and the stator layer 106. In some implementations, the cover layer 102 may include or support a MEMS element 102a, such as a MEMS mirror device. Although some implementations are described herein in terms of a MEMS mirror device, other types of MEMS devices are contemplated, such as MEMS devices with other types of optical elements (e.g., prisms, switches, filters, gratings, or lenses). Although some implementations are described herein in terms of a two-layer or three-layer MEMS mirror devices, other configurations are contemplated.

In some implementations, the rotor layer 104 includes a rotor comb 110 and one or more hinges 112. For example, the rotor layer 104 may be suspended above the stator layer 106 by the one or more hinges 112. In this case, when a driving voltage is applied to the stator layer 106, a portion of the rotor layer 104 is caused to rotate about the one or more hinges 112, thereby actuating a MEMS element 102a. In some implementations, the stator layer 106 includes a stator comb 114 and an anchor 116. For example, the stator layer 106 may include a stator comb 114 with a set of stator teeth. In a MEMS device, a rotor and stator may be intermeshed to actuate a MEMS element 102a of the MEMS device. For example, in the MEMS device 100, first teeth of the rotor comb 110 and second teeth of the stator comb 114 are intermeshed to tilt a MEMS mirror about the hinge 112 and an associated axis when a driving voltage is applied to the stator comb 114. Although some implementations are described herein in terms of a comb-type of MEMS device, other types of MEMS devices are contemplated, such as parallel plate MEMS devices. For example, rather than rotor comb 110 and stator combs 114, a MEMS device may include other types of actuating elements or movable elements.

In some implementations, the stator layer 106 may include a set of bonding pillars 118. For example, the stator layer 106 is formed with structures including the stator comb 114, the anchor 116, and the set of bonding pillars 118. When the MEMS device 100 is being manufactured or assembled, the bonding pillars 118 may attach to corresponding rotor pillar regions 120. The rotor pillar regions 120 may further attach to a set of cover pillar regions 122. The bonding pillars 118 provide structural support for the rotor layer 104 when forming rotor structures on the rotor layer 104, such as the rotor comb 110 and the hinges 112 and for the cover layer 102 when the cover layer 102 is being attached to the rotor layer 104. After attachment of the cover layer 102 to the rotor layer 104 (and formation of features or structures on the rotor layer 104), an etching procedure is performed to release the rotor layer 104 from the rotor pillar regions 120 and the cover layer 102 from the cover pillar regions 122. Based on the rotor layer 104 and cover layer 102 being isolated from the rotor pillar regions 120 and the cover pillar regions 122, respectively, the rotor layer 104 and cover layer 102 remain attached to the stator layer 106 via a rotor frame 124 and a cover frame 126. The rotor comb 110 remains suspended above the stator comb 114 by the hinges 112 (which are attached to the rotor frame 124), and the MEMS element 102a is attached to the rotor comb 110, such that the MEMS element 102a is actuated when the rotor comb 110 is actuated (and the rotor frame 124 and cover frame 126 remain fixed).

As indicated above, FIG. 1 is provided as an example. Other examples may differ from what is described with regard to FIG. 1.

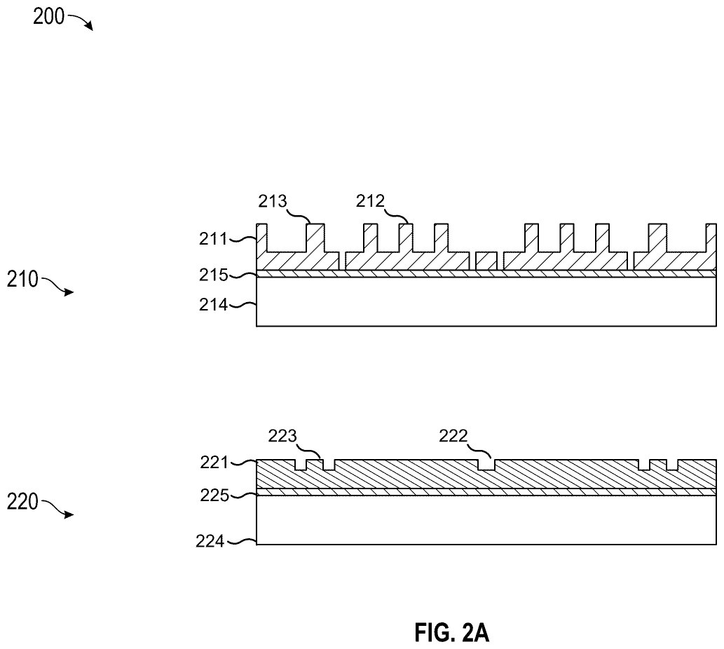

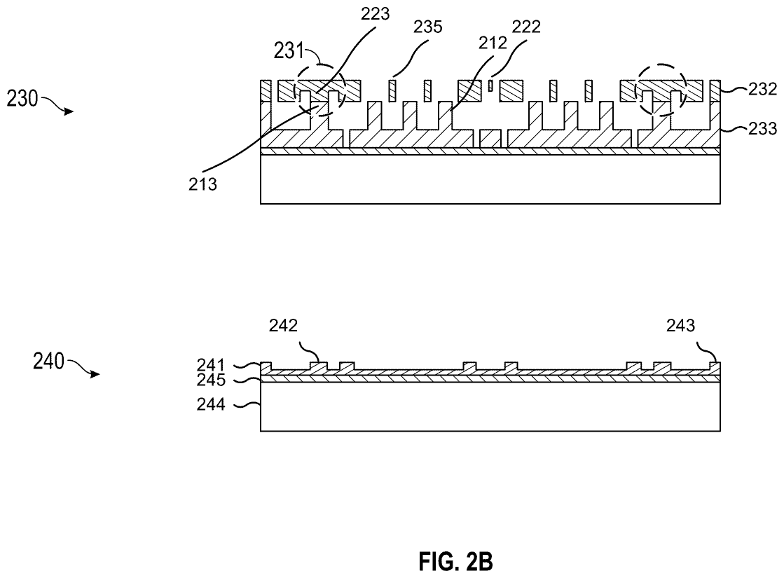

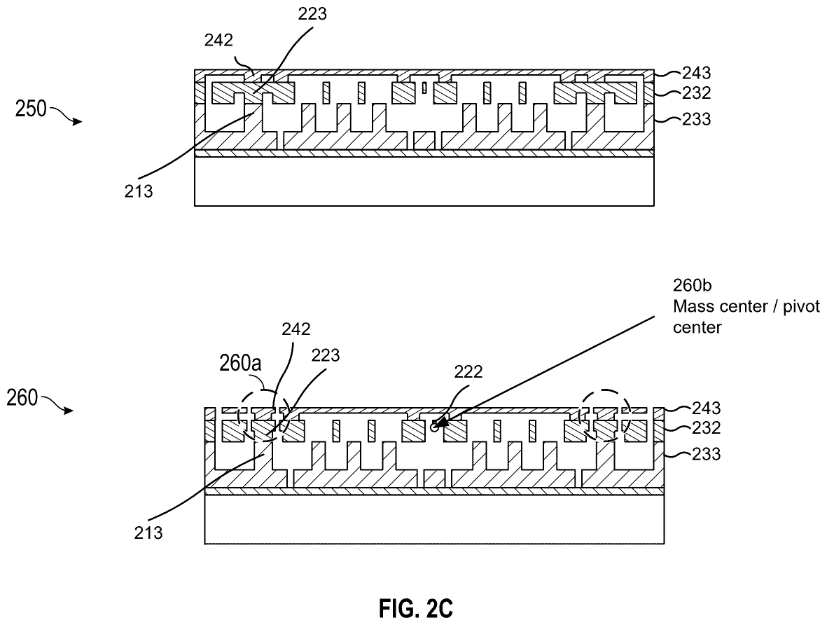

FIGS. 2A-2C are diagrams of an example implementation 200 associated with bonding pillar structure for hidden comb microelectromechanical system.

As shown in FIG. 2A, a step 210 includes formation of a stator wafer. For example, one or more timed etch steps or through layer etch steps may be applied to a stator wafer to form a set of stator structures 211 on the stator wafer. In this case, the set of stator structures 211 may include a set of stator teeth 212 or a set of bonding pillars 213, among other examples. In some implementations, a deposition step may be used to form the stator wafer, which is then shaped using the one or more timed etch steps or through layer etch steps. In some implementations, the stator wafer is provided on a handle 214, which may be bonded to the stator wafer by a bonding layer 215 (e.g., a silicon oxide layer, such as is used in a silicon on insulator (SOI) wafer or for anodic bonding, or other intermediate layer to facilitate bonding of the stator wafer to the handle 214).

As further shown in FIG. 2A, a step 220 includes formation of a rotor wafer. For example, a timed etch step may be used to define, on a rotor layer 221, a hinge 222 or a set of rotor pillar regions 223 that are to be attached to the set of bonding pillars 213. In some implementations, the rotor wafer is provided on a handle 224, which may be bonded to the rotor wafer by a bonding layer 225.

As shown in FIG. 2B, in a step 230, the stator wafer and the rotor wafer are attached to form an assembly. For example, the rotor wafer may be flipped in orientation and attached to the stator wafer, such that, at reference number 231, a rotor pillar region 223 is attached to a bonding pillar 213. Similarly, a frame 232 of the rotor wafer is attached to a frame 233 of the stator wafer. As shown, based on bonding the rotor wafer to the stator wafer, the handle 224 and bonding layer 225 may be removed from the rotor wafer, thereby exposing the rotor wafer for structure formation. For example, the rotor wafer and the stator wafer may be subjected to one or more timed or through etch steps to form one or more rotor structures, such as a set of rotor teeth 235 or the hinge 222. The rotor teeth 235 may be formed to intermesh with the teeth 212, without touching, thereby enabling a driving voltage to drive actuation between the rotor wafer and the stator wafer. The rotor pillar region 223 and the bonding pillar 213 may be omitted from the through etch steps to ensure that the rotor wafer remains supported while the set of rotor structures are being formed and while a cover is being attached, as described in more details herein.

As further shown in FIG. 2B, in a step 240, a cover wafer may be formed. For example, a timed etch step may be used to form one or more areas or features 241 of the cover wafer, such as a set of cover pillar regions 242 or a frame 243 that are to be aligned to and bonded to the set of rotor pillar regions 223 and the frame 232, respectively. In some implementations, the cover wafer is provided on a handle 244, which is bonded to the cover wafer via a bonding layer 245.

As shown in FIG. 2C, in a step 250, the cover wafer is attached to the rotor wafer. For example, the cover wafer is flipped in orientation and attached onto the rotor wafer, such that rotor pillar regions 223 of the rotor wafer align to cover pillar regions 242 of the cover wafer and to the bonding pillars 213 of the stator wafer. Similarly, the frame is bonded to the frame 232 and to the frame 233, thereby forming an assembly. As further shown in FIG. 2C, in a step 260, the handle 244 and the bonding layer 245 may be removed from the cover wafer to expose the cover wafer. Furthermore, one or more through layer etch steps are applied to the cover wafer, the rotor wafer, or the stator wafer to detach the cover wafer and the rotor wafer from the set of bonding pillars 213, the rotor pillar region 223, and the cover pillar region 242. In other words, the set of cover pillar regions 242 and the set of rotor pillar regions 223 are etched to isolate the set of cover pillar regions 242 and the set of rotor pillar regions 223 from the cover wafer and the rotor wafer, respectively, as shown by reference number 260a, to form a MEMS device. The frames 243, 232, and 233 remain bonded together to enclose the MEMS device. As shown by reference number 260b, a mass center and a pivot center of the MEMS device are aligned at a same point (e.g., at the hinge 222).

As indicated above, FIGS. 2A-2C are provided as examples. Other examples may differ from what is described with regard to FIGS. 2A-2C.

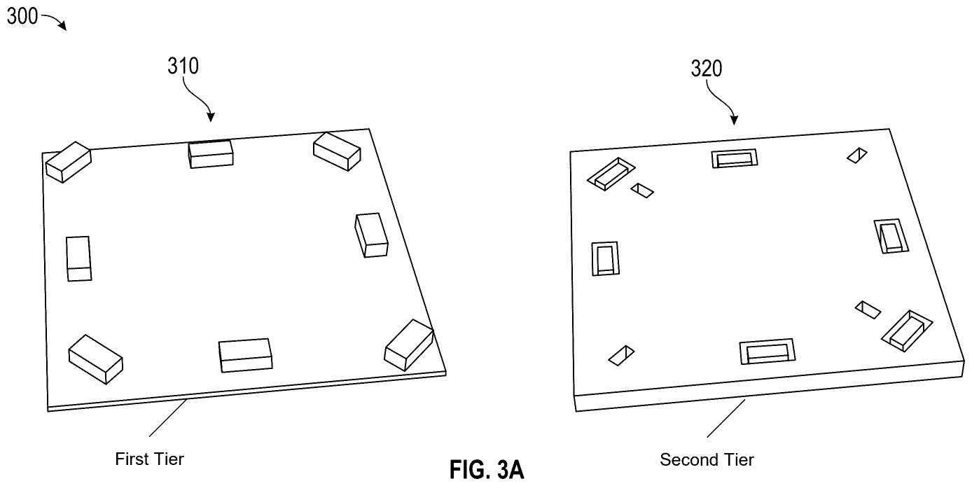

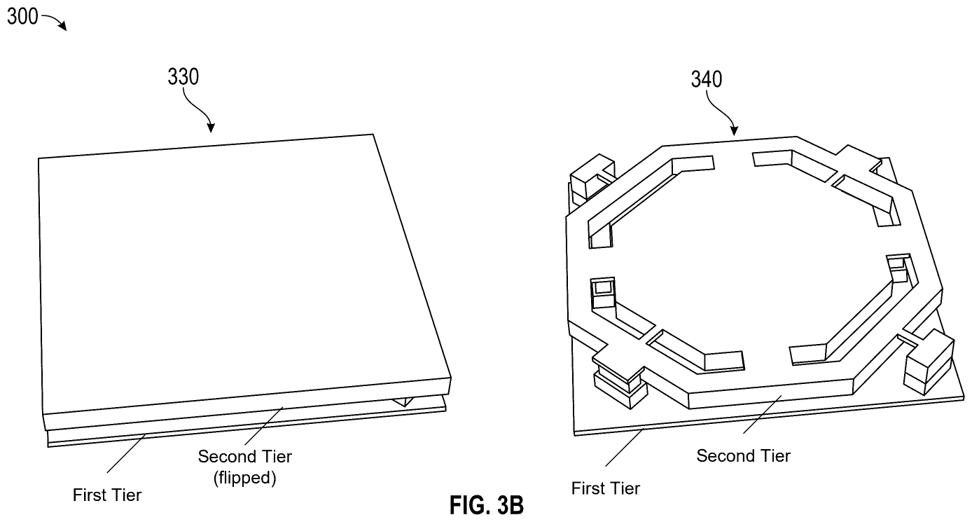

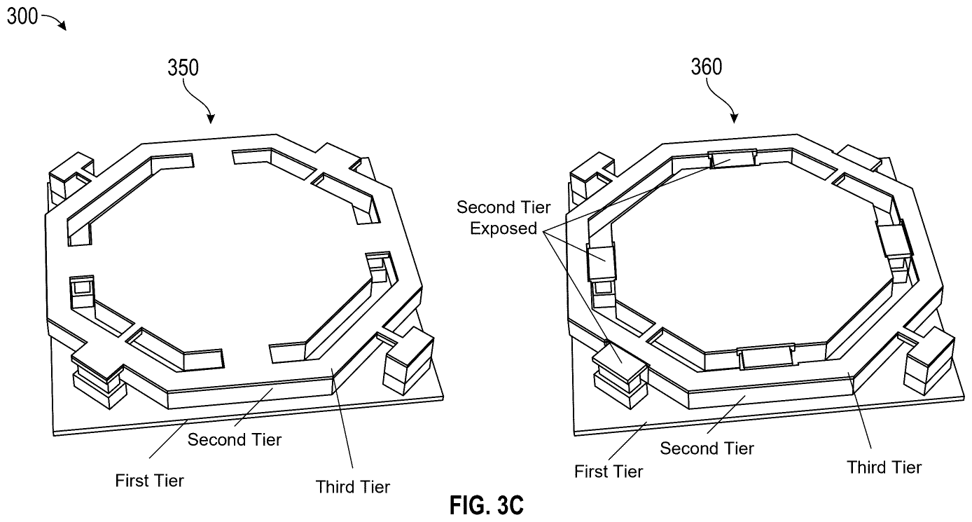

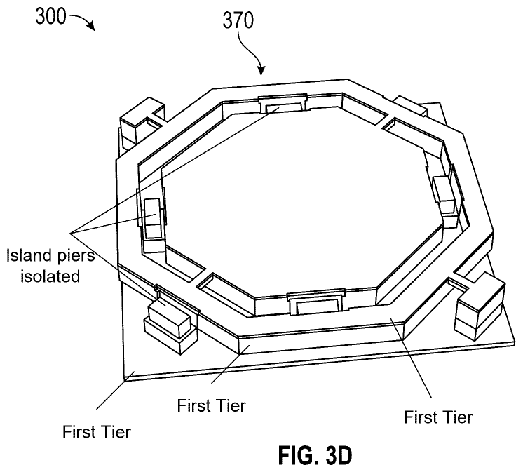

FIGS. 3A-3D are diagrams of an example implementation 300 associated with bonding pillar structure for hidden comb microelectromechanical system.

As shown in FIG. 3A, in a first step 310, a first tier (e.g., a silicon wafer, which may form a layer, such as a rotor layer, stator layer, cover layer, or other layer of a MEMS device, as described herein) is patterned to form a foundation for a set of structures, such as anchor structures and bonding pillar structures. As shown in a second step 320, a second tier is partially etched from a bottom to form a set of structures on the next tier. As shown in FIG. 3B, and in a third step 330, the second tier is flipped, aligned, and bonded to the first tier. In a fourth step 340, a set of fine features are formed on the first tier and the second tier, such as rotor combs and stator combs, by etching patterns into the first tier and the second tier. As shown in FIG. 3C, and in a fifth step 350, a third tier is disposed on the second tier and patterned with one or more features corresponding to features formed on the first tier and the second tier. In a sixth step 360, a set of bonding pillars are exposed (e.g., the third tier is partially removed to expose the second tier), using a shallow etch. As shown in FIG. 3D, and in a seventh step 370, the set of bonding pillars are etched to release the set of bonding pillars (and layers deposited thereon) from the first through third tiers (e.g., the second tier is partially removed to isolate island piers from a remainder of a structure).

As indicated above, FIGS. 3A-3D are provided as examples. Other examples may differ from what is described with regard to FIGS. 3A-3D.

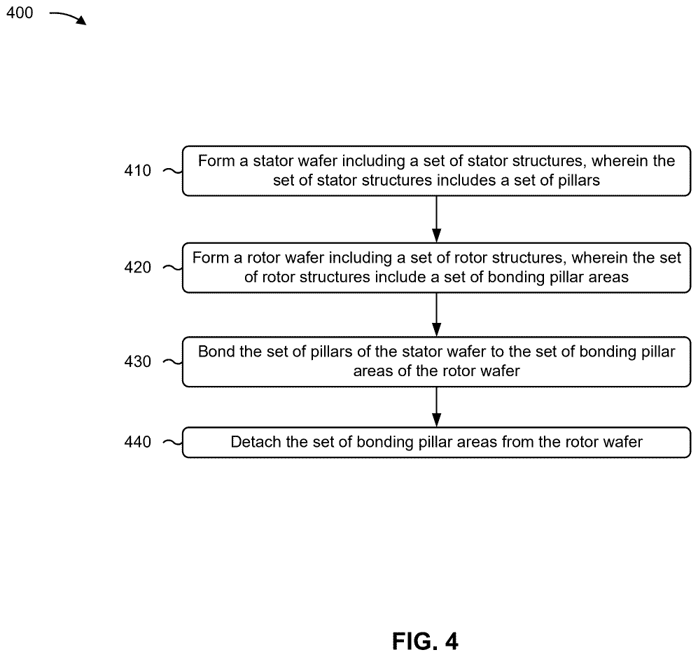

FIG. 4 is a flowchart of an example process 400 associated with using a bonding pillar structure for a hidden comb MEMS device. One or more process blocks of FIG. 4 are performed by a device (e.g., a layer deposition device, an etching device, or an alignment device, among other examples) and/or by another device or a group of devices separate from or including the device.

As shown in FIG. 4, process 400 includes forming a stator wafer including a set of stator structures, wherein the set of stator structures includes a set of pillars (block 410). For example, the device may form a stator wafer including a set of stator structures, wherein the set of stator structures includes a set of pillars, as described above. In some aspects, the set of stator structures includes a set of pillars.

As further shown in FIG. 4, process 400 includes forming a rotor wafer including a set of rotor structures, wherein the set of rotor structures include a set of bonding pillar areas (block 420). For example, the device may form a rotor wafer including a set of rotor structures, wherein the set of rotor structures include a set of bonding pillar areas, as described above. In some aspects, the set of rotor structures include a set of bonding pillar areas.

As further shown in FIG. 4, process 400 includes bonding the set of pillars of the stator wafer to the set of bonding pillar areas of the rotor wafer (block 430). For example, the device may bond the set of pillars of the stator wafer to the set of bonding pillar areas of the rotor wafer, as described above.

As further shown in FIG. 4, process 400 includes detaching the set of bonding pillar areas from the rotor wafer (block 440). For example, the device may detach the set of bonding pillar areas from the rotor wafer, as described above.

Process 400 may include additional aspects, such as any single aspect or any combination of aspects described below and/or in connection with one or more other processes described elsewhere herein.

In a first aspect, process 400 includes etching the rotor wafer to detach the set of rotor structures from an anchored frame. Additionally, or alternatively, detaching the set of pillars from the stator wafer may include through-etching to form a set of gaps around the set of bonding pillar areas.

In a second aspect, alone or in combination with the first aspect, process 400 includes forming a cover wafer, wherein the cover wafer includes a set of cover pillar areas, and bonding the cover wafer to the rotor wafer, such that the set of cover pillar areas is bonded to the set of bonding pillar areas.

In a third aspect, alone or in combination with one or more of the first and second aspects, detaching the set of bonding pillar areas from the rotor wafer comprises through-etching to form a set of gaps around the set of cover pillar areas.

In a fourth aspect, alone or in combination with one or more of the first through third aspects, bonding the cover wafer to the rotor wafer comprises aligning the cover wafer to the rotor wafer with a set of alignment marks being alignment features for the aligning. Additionally, or alternatively, the bonding may include aligning the cover wafer to the rotor wafer with the set of cover pillar areas and the set of bonding pillar areas being alignment features for the aligning.

In a fifth aspect, alone or in combination with one or more of the first through fourth aspects, bonding the set of pillars to the set of bonding pillar areas comprises aligning the stator wafer with the rotor wafer with a set of alignment marks being alignment features for the aligning. Additionally, or alternatively, the aligning may include aligning the stator wafer with the rotor wafer using the set of pillars and the set of bonding pillar areas being alignment features for the aligning.

In a sixth aspect, alone or in combination with one or more of the first through fifth aspects, one or more features of MEMS device are formed using a timed-etching procedure or a through-etching procedure.

In a seventh aspect, alone or in combination with one or more of the first through sixth aspects, forming the rotor wafer comprises forming a tilting pivot at a mass center of a movable portion of the MEMS device.

Although FIG. 4 shows example blocks of process 400, in some implementations, process 400 includes additional blocks, fewer blocks, different blocks, or differently arranged blocks than those depicted in FIG. 4. Additionally, or alternatively, two or more of the blocks of process 400 may be performed in parallel.

The foregoing disclosure provides illustration and description, but is not intended to be exhaustive or to limit the implementations to the precise forms disclosed. Modifications and variations may be made in light of the above disclosure or may be acquired from practice of the implementations. Furthermore, any of the implementations described herein may be combined unless the foregoing disclosure expressly provides a reason that one or more implementations may not be combined.

As used herein, satisfying a threshold may, depending on the context, refer to a value being greater than the threshold, greater than or equal to the threshold, less than the threshold, less than or equal to the threshold, equal to the threshold, not equal to the threshold, or the like.

Even though particular combinations of features are recited in the claims and/or disclosed in the specification, these combinations are not intended to limit the disclosure of various implementations. In fact, many of these features may be combined in ways not specifically recited in the claims and/or disclosed in the specification. Although each dependent claim listed below may directly depend on only one claim, the disclosure of various implementations includes each dependent claim in combination with every other claim in the claim set. As used herein, a phrase referring to “at least one of” a list of items refers to any combination of those items, including single members. As an example, “at least one of: a, b, or c” is intended to cover a, b, c, a-b, a-c, b-c, and a-b-c, as well as any combination with multiple of the same item.

When a component or one or more components (e.g., a manufacturing device or one or more manufacturing devices) is described or claimed (within a single claim or across multiple claims) as performing multiple operations or being configured to perform multiple operations, this language is intended to broadly cover a variety of architectures and environments. For example, unless explicitly claimed otherwise (e.g., via the use of “first component” and “second component” or other language that differentiates components in the claims), this language is intended to cover a single component performing or being configured to perform all of the operations, a group of components collectively performing or being configured to perform all of the operations, a first component performing or being configured to perform a first operation and a second component performing or being configured to perform a second operation, or any combination of components performing or being configured to perform the operations. For example, when a claim has the form “one or more components configured to: perform X; perform Y; and perform Z,” that claim should be interpreted to mean “one or more components configured to perform X; one or more (possibly different) components configured to perform Y; and one or more (also possibly different) components configured to perform Z.”

No element, act, or instruction used herein should be construed as critical or essential unless explicitly described as such. Also, as used herein, the articles “a” and “an” are intended to include one or more items, and may be used interchangeably with “one or more.” Further, as used herein, the article “the” is intended to include one or more items referenced in connection with the article “the” and may be used interchangeably with “the one or more.” Furthermore, as used herein, the term “set” is intended to include one or more items (e.g., related items, unrelated items, or a combination of related and unrelated items), and may be used interchangeably with “one or more.” Where only one item is intended, the phrase “only one” or similar language is used. Also, as used herein, the terms “has,” “have,” “having,” or the like are intended to be open-ended terms. Further, the phrase “based on” is intended to mean “based, at least in part, on” unless explicitly stated otherwise. Also, as used herein, the term “or” is intended to be inclusive when used in a series and may be used interchangeably with “and/or,” unless explicitly stated otherwise (e.g., if used in combination with “either” or “only one of”). Further, spatially relative terms, such as “below,” “lower,” “above,” “upper,” and the like, may be used herein for ease of description to describe one element or feature's relationship to another element(s) or feature(s) as illustrated in the figures. The spatially relative terms are intended to encompass different orientations of the apparatus, device, and/or element in use or operation in addition to the orientation depicted in the figures. The apparatus may be otherwise oriented (rotated 90 degrees or at other orientations) and the spatially relative descriptors used herein may likewise be interpreted accordingly.

What is claimed is:

1. A microelectromechanical system (MEMS) device, comprising:
a stator layer, comprising:
an anchor structure,
a stator structure attached to the anchor structure, and
a set of bonding pillars configured to be attached to the anchor structure;
a rotor layer disposed on the stator layer, comprising:
a rotor structure,
a hinge, and
a set of rotor pillar regions,
wherein each bonding pillar, of the set of bonding pillars, is configured to be bonded to a respective rotor pillar region of the set of rotor pillar regions; and
a cover layer disposed on the rotor layer, comprising:
a cover structure, and
a set of cover pillar regions,
wherein each cover pillar region, of the set of cover pillar regions, is bonded to a respective rotor pillar region of the set of rotor pillar regions.

2. The MEMS device of claim 1, wherein the set of bonding pillars is formed attached to, and etched to be detached from the set of rotor pillar regions, such that the rotor layer is movable with respect to the stator layer.

3. The MEMS device of claim 1, wherein a mass center of the MEMS device is aligned to a pivot center of the rotor layer to within a threshold tolerance level.

4. The MEMS device of claim 1, wherein the stator structure includes a set of stator teeth.

5. The MEMS device of claim 4, wherein the rotor structure includes a set of rotor teeth.

6. The MEMS device of claim 5, wherein the set of stator teeth is aligned to the set of rotor teeth to within a threshold tolerance level.

7. A method of manufacturing a microelectromechanical system (MEMS) device, comprising:
forming, by a device, a stator wafer including a set of stator structures,
wherein the set of stator structures includes a set of pillars;
forming, by the device, a rotor wafer including a set of rotor structures,
wherein the set of rotor structures include a set of bonding pillar areas;
bonding, by the device, the set of pillars of the stator wafer to the set of bonding pillar areas of the rotor wafer; and
detaching, by the device, the set of bonding pillar areas from the rotor wafer.

8. The method of claim 7, further comprising:
etching the rotor wafer to detach the set of rotor structures from an anchored frame.

9. The method of claim 7, further comprising:
forming a cover wafer,
wherein the cover wafer includes a set of cover pillar areas; and
bonding the cover wafer to the rotor wafer, such that the set of cover pillar areas is bonded to the set of bonding pillar areas.

10. The method of claim 9, wherein detaching the set of bonding pillar areas from the rotor wafer comprises:
through-etching to form a set of gaps around the set of cover pillar areas.

11. The method of claim 9, wherein bonding the cover wafer to the rotor wafer comprises:
aligning the cover wafer to the rotor wafer with a set of alignment marks being alignment features for the aligning.

12. The method of claim 7, wherein bonding the set of pillars to the set of bonding pillar areas comprises:
aligning the stator wafer with the rotor wafer with a set of alignment marks being alignment features for the aligning.

13. The method of claim 7, wherein one or more features of MEMS device are formed using a timed-etching procedure or a through-etching procedure.

14. The method of claim 7, wherein forming the rotor wafer comprises:
forming a tilting pivot at a mass center of a movable portion of the MEMS device.

15. An optical system, comprising:
a microelectromechanical system (MEMS) device, comprising:
a stator layer, comprising:
an anchor structure,
a stator structure attached to the anchor structure, and
a set of bonding pillars configured to be attached to the anchor structure;
a rotor layer disposed on the stator layer, comprising:
a rotor structure,
a hinge, and
a set of rotor pillar regions,
wherein each bonding pillar, of the set of bonding pillars, is configured to be bonded to a respective rotor pillar region of the set of rotor pillar regions; and
a MEMS element disposed above the rotor layer, such that the MEMS element is movable in connection with movement of the rotor layer relative to the stator layer.

16. The optical system of claim 15, wherein the MEMS element includes at least one of:
a mirror,
a lens,
a grating,
a prism,
a laser, or
a switch.

17. The optical system of claim 15, wherein the MEMS element is movable about the hinge.

18. The optical system of claim 15, wherein the optical system includes at least one of:
an optical communications system,
an optical measurement system,
an optical manufacturing system, or
an optical imaging system.

19. The optical system of claim 15, further comprising:
a cover layer disposed on the rotor layer, comprising:
a cover structure, and
a set of cover pillar regions,
wherein each cover pillar region, of the set of cover pillar regions, is bonded to a respective rotor pillar region of the set of rotor pillar regions.

20. The optical system of claim 15, wherein a mass center of the MEMS device is aligned to a pivot center of the rotor layer to within a threshold tolerance level.
